(19) United States
(12) Patent Application Publication
(10) Pub. No.: US 2025/0362710 A1
(43) Pub. Date: Nov. 27, 2025

(54) DISPLAY DEVICE

(71) Applicant: Samsung Display Co., Ltd., Yongin-si (KR)

(72) Inventor: TAEAN SEO, Yongin-si (KR)

(21) Appl. No.: 19/050,972

(22) Filed: Feb. 11, 2025

(30) Foreign Application Priority Data
May 24, 2024 (KR) 10-2024-0067793
Jun. 27, 2024 (KR) 10-2024-0084702

(51) Int. Cl. G06F 1/16

(52) U.S. Cl. CPC G06F 1/1656; G06F 1/1616; G06F 1/1652

(57) ABSTRACT

Provided is a display device. The display device includes a display panel including a fixed area, and an extension area extending in a first direction from the fixed area, a support plate including a first plate overlapping the fixed area, and including a flat part parallel to a plane defined by the first direction and by a second direction crossing the first direction, and an inclined part extending in the first direction from the flat part, and a second plate overlapping the extension area, and below a bottom surface of the inclined part, and an adhesion member between the display panel and the support plate.

### CROSS-REFERENCE TO RELATED APPLICATION

The present application claims priority to, and the benefit of, Korean Patent Application No. 10-2024-0067793, filed on May 24, 2024, and Korean Patent Application No. 10-2024-0084702, filed on Jun. 27, 2024, in the Korean Intellectual Property Office, the entire disclosures of which are incorporated herein by reference.

### BACKGROUND

### 1. Field

The present disclosure herein relates to a display device.

### 2. Description of the Related Art

In general, electronic devices that provide images to users, such as smartphones, digital cameras, laptop computers, navigation devices, and smart televisions include a display device for displaying images. The display device generates an image, and provides the image to the user through a display screen.

Recently, with the development of display device technology, various types of display devices have been developed. For example, flexible display devices, which may be slid or wound and extended outside the case, are being developed. Flexible display devices, which may be deformed in various shapes, are portable, and may improve user convenience.

### SUMMARY

The present disclosure provides a display device with improved folding and sliding reliability and improved surface quality.

One or more embodiments of the present disclosure provide a display device including a display panel including a fixed area, and an extension area extending in a first direction from the fixed area, a support plate including a first plate overlapping the fixed area, and including a flat part parallel to a plane defined by the first direction and by a second direction crossing the first direction, and an inclined part extending in the first direction from the flat part, and a second plate overlapping the extension area, and below a bottom surface of the inclined part, and an adhesion member between the display panel and the support plate.

A height of a top surface of the inclined part may decrease toward the second plate.

A top surface of the first plate and a top surface of the second plate may have a height difference.

The adhesion member may include a first adhesion part above the top surface of the second plate and the top surface of the inclined part, and a second adhesion part above a top surface of the flat part and a top surface of the first adhesion part.

A height of the top surface of the first adhesion part may be the same as a height of the top surface of the flat part.

The top surface of the inclined part may include a pattern part.

The top surface of the first plate and the top surface of the second plate may include a pattern part.

An elastic modulus of the first adhesion part may be greater than an elastic modulus of the second adhesion part.

The flat part may include a first non-folding part, a folding part defining openings, and a second non-folding part arranged in the first direction.

The second plate may include first portions parallel to the plane defined by the first direction and the second direction, and second portions respectively between adjacent ones of the first portions that are adjacent to each other in the first direction, and defining flexible openings.

The display device may further include support bars coupled to bottom surfaces of the first portions, arranged in the first direction, and extending in the second direction.

In one or more embodiments of the present disclosure, a display device may

include a display panel including a fixed area, and an extension area extending in a first direction from the fixed area, a second plate below the extension area, a first plate below the fixed area, and having one side, which is adjacent to the second plate and which is opposite to an opposite side in the first direction, having a thickness that is less than a thickness of the opposite side, support bars coupled to a bottom surface of the second plate, and an adhesion member between the display panel and the first plate, and between the display panel and the second plate.

A height of a top surface of the one side of the first plate may be lower than a height of a top surface of the opposite side of the first plate.

The top surface of the one side of the first plate may be inclined.

The second plate may overlap the one side of the first plate.

The adhesion member may include a first adhesion part above a top surface of the one side of the first plate and above a top surface of the second plate, and a second adhesion part above a top surface of the first adhesion part and above a top surface of the opposite side of the first plate.

A height of the top surface of the first adhesion part may be the same as a height of the top surface of the opposite side of the first plate.

The top surface of the one side of the first plate may include a pattern part.

A top surface of the first plate and the top surface of the second plate may include pattern parts.

An elastic modulus of the first adhesion part may be greater than an elastic modulus of the second adhesion part.

In one or more embodiments of the present disclosure, an electronic device may include a display device including a display panel including a fixed area, and an extension area extending in a first direction from the fixed area, a support plate including a first plate overlapping the fixed area, and including a flat part parallel to a plane defined by the first direction and by a second direction crossing the first direction, and an inclined part extending in the first direction from the flat part, and a second plate overlapping the extension area, and below a bottom surface of the inclined part, and an adhesion member between the display panel and the support plate.

The electronic device may include a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, or a head-mounted display (HMD).

### BRIEF DESCRIPTION OF THE DRAWINGS

The accompanying drawings are included to provide a further understanding of the present disclosure, and are incorporated in and constitute a part of this specification. The drawings illustrate embodiments of the present disclosure and, together with the description, serve to explain principles of the present disclosure. In the drawings:

FIG. 1 is a perspective view of a display device according to one or more embodiments of the present disclosure;

FIG. 2 is a view illustrating the folded state of the display device shown in FIG. 1;

FIG. 3 is a view for explaining an extension mode of the display device shown in FIG. 1;

FIG. 4 is an exploded perspective view of the display device shown in FIGS. 1 to 3;

FIGS. 5A and 5B are views for explaining a reduction mode and an extension mode of a module set shown in FIG. 4;

FIG. 6 is a cross-sectional view of a display module shown in FIG. 5A;

FIG. 7 is a cross-sectional view of a display panel shown in FIG. 6;

FIG. 8 is a perspective view of a support plate shown in FIG. 5A;

FIG. 9 is an enlarged plan view of a first area AA1 shown in FIG. 8;

FIG. 10 is a cross-sectional view of a portion taken along the line I-I′ of FIG. 8;

FIG. 11 is a perspective view of a first plate according to one or more embodiments of present disclosure;

FIGS. 12A to 12D are enlarged plan views of a second area AA2 shown in FIG. 11;

FIG. 13 is a perspective view of the first plate and a second plate according to one or more embodiments of the present disclosure;

FIG. 14 is a perspective view of support bars shown in FIG. 5A; and

FIG. 15 is a cross-sectional view for explaining support bars coupled to the bottom surface of the second plate.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.” Furthermore, the expression “being the same” may mean “being substantially the same”. In other words, the expression “being the same” may include a range that can be tolerated by those of ordinary skill in the art. The other expressions may also be expressions from which “substantially” has been omitted.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

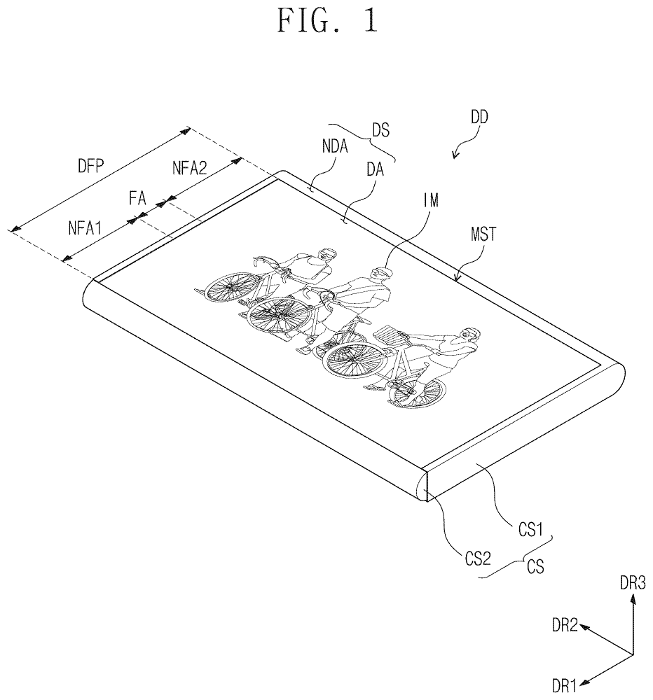

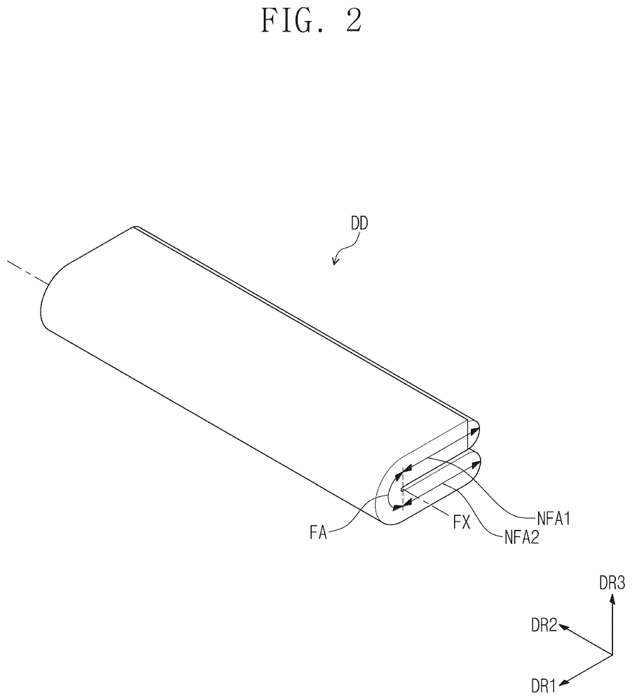

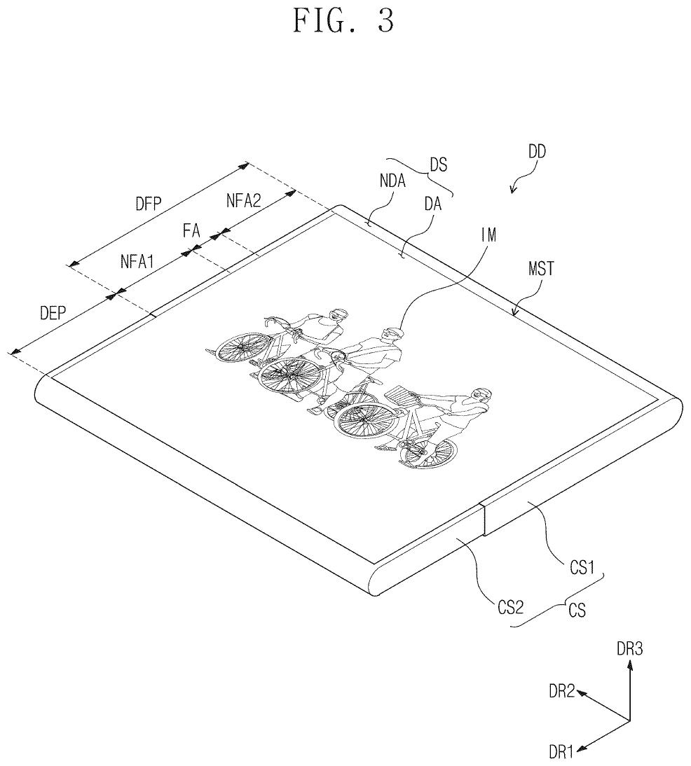

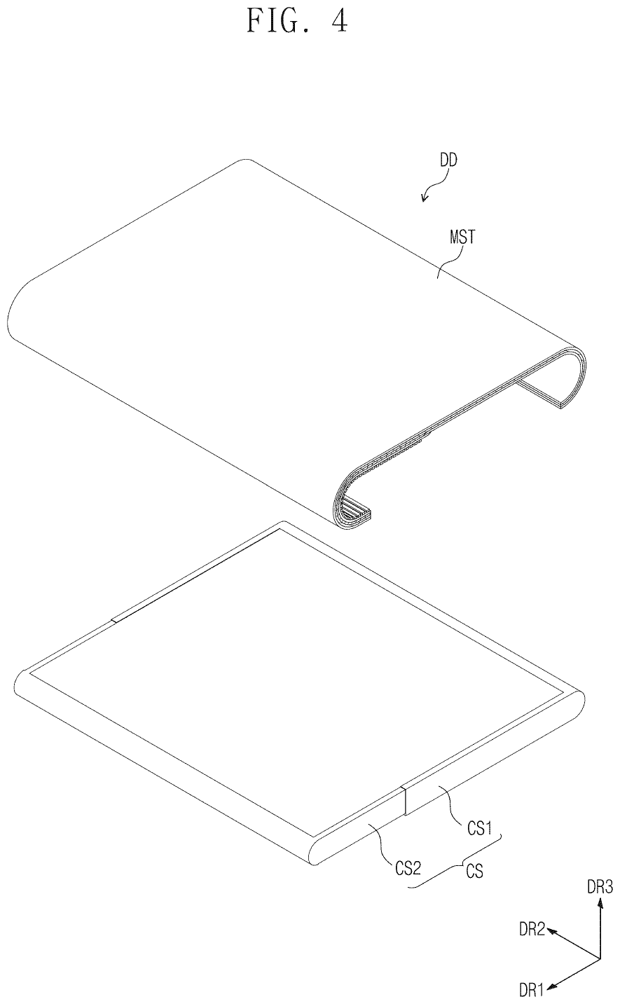

FIG. 1 is a perspective view of a display device according to one or more embodiments of the present disclosure. FIG. 2 is a view illustrating the folded state of the display device shown in FIG. 1. FIG. 3 is a view for explaining an extension mode of the display device shown in FIG. 1. FIG. 4 is an exploded perspective view of the display device shown in FIGS. 1 to 3.

Referring to FIGS. 1 and 2, a display device DD may have a rectangular shape having a short side extending in the first direction DR1, and a long side extending in the second direction DR2 crossing the first direction. However, the display device DD is not limited thereto and may have various shapes, such as circular and polygonal shapes. The display device DD may be a flexible display device.

Hereinafter, a direction crossing the first direction DR1 will be defined as the second direction DR2. A direction, which is substantially vertical with respect to the plane defined by the first and second directions DR1, DR2, will be defined as a third direction DR3. In this specification, the term “when viewed in a plane” or “in plan view” may mean a state viewed from the third direction DR3.

The display device DD may include a folding area FA and a plurality of non-

folding areas NFA1, NFA2. The non-folding areas NFA1, NFA2 may include a first non-folding area NFA1 and a second non-folding area NFA2. The folding area FA may be located between the first non-folding area NFA1 and the second non-folding area NFA2. The folding area FA, the first non-folding area NFA1, and the second non-folding area NFA2 may be arranged in the first direction DR1.

For example, a single folding area FA and two non-folding areas NFA1, NFA2 are illustrated, however, the number of folding areas FA and non-folding areas NFA1, NFA2 is not limited thereto. For example, the display device DD may include a plurality of non-folding areas more than two, and a plurality of folding areas respectively located between the non-folding areas.

The top surface of the display device DD may be defined as a display surface DS, and the display surface DS may have a plane defined by the first direction DR1 and the second direction DR2. Images IM generated by the display device DD may be provided to the user through the display surface DS.

The display surface DS may include a display area DA, and a non-display area NDA surrounding the display area DA (e.g., in plan view). The display area DA displays an image, and the non-display area NDA may not display an image. The non-display area NDA may surround the display area DA, and may define an edge of the display device DD printed in a corresponding color (e.g., predetermined color).

The display device DD according to one or more embodiments is a device that displays a moving image and/or a still image. The display device DD may be applied to portable electronic devices, such as mobile phones, smartphones, tablet personal computers (PCs), mobile communication terminals, electronic notebooks, electronic books, portable multimedia players (PMPs), navigations, and ultra-mobile PCs (UMPCs). For example, the display device DD may be applied to a display unit of a television, a laptop computer, a monitor, a billboard, or the Internet of Things (IoT). Alternatively, in one or more embodiments, the display device DD may be applied to a smartwatch, a watch phone, and/or a head-mounted display device (HMD) for implementing virtual reality and/or augmented reality.

Referring to FIG. 2, the display device DD may be a display device DD that may be folded or unfolded. For example, the folding area FA may be bent based on a folding axis FX parallel to the second direction DR2 to fold the display device DD. The folding axis FX may be defined as a long axis parallel to the long side of the display device DD.

When the display device DD is folded, the first non-folding area NFA1 and the second non-folding area NFA2 may face each other, and the display device DD may be in-folded so that the display surface DS is not exposed to the outside. However, the present disclosure is not limited thereto.

Referring to FIGS. 3 and 4, the display device DD may include a module set MST and a case CS. The case CS may accommodate the module set MST. Both sides of the case CS, which are opposite to each other in the first direction DR1, may have a curved shape.

The case CS may include a first case CS1 and a second case CS2. The second case CS2 may move in a direction away from or toward the first case CS1 along the first direction DR1.

The module set MST may be accommodated in the case CS, and may display an image IM. One side of the module set MST, of the sides that are opposite to each other in the first direction DR1, may be accommodated in the first case CS1. The other side of the module set MST may be accommodated in the second case CS2. Accordingly, when the second case CS2 moves from the first case CS1 in the first direction DR1, the module set MST may also move in the first direction DR1. When the second case CS2 moves in the first direction DR1, the area of the exposed surface of the module set MST may be adjusted in accordance with the movement of the second case CS2. The reduced mode and the extended mode of the display device DD may be implemented according to the movement of the second case CS2.

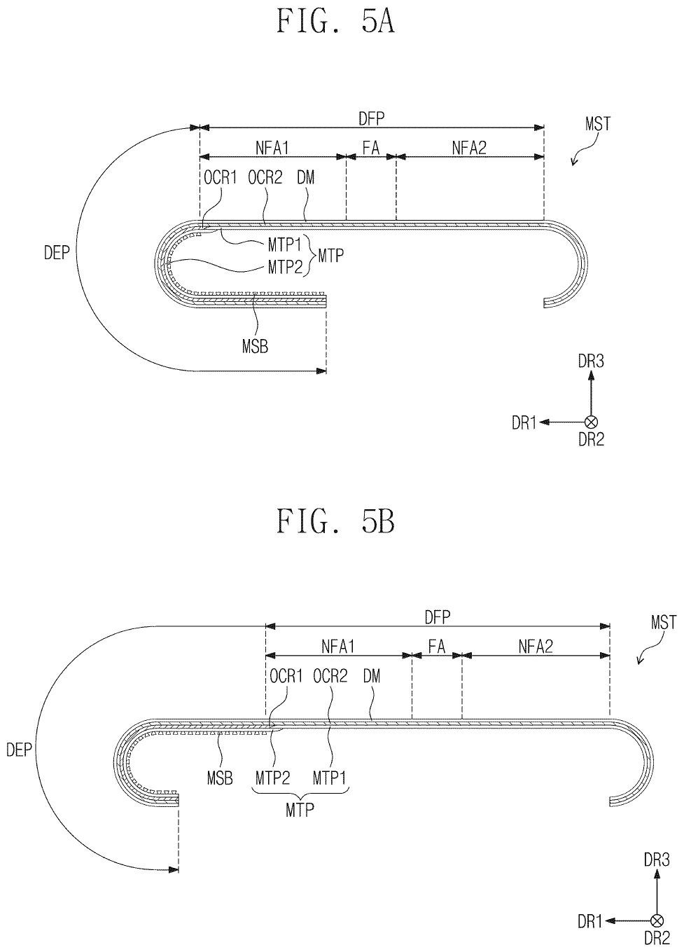

FIGS. 5A and 5B are views for explaining the reduced mode and the extended mode of the module set shown in FIG. 4.

For example, FIGS. 5A and 5B are side views when viewed from the second direction DR2.

In descriptions of components illustrated in FIGS. 5A and 5B, the same components as those described with reference to the above-described drawings will be omitted or briefly described.

Referring to FIGS. 4, 5A, and 5B, the module set MST may include a display module DM, a support plate MTP, an adhesion member OCR (e.g., OCR1, OCR2), and a plurality of support bars MSB. The display module DM may be a flexible display module. The display module DM may include a fixed area DFP and an extension area DEP. When the display device DD is in a reduced mode, a portion of the display module DM that is flat and exposed to the outside is defined as the fixed area DFP, and a portion of the display module DM not exposed flat to the outside is defined as the extension area DEP. The first non-folding area NFA1, the folding area FA, and the second non-folding area NFA2 may be defined in the fixed area DFP.

When the display device DD is in a reduced mode or an extended mode, a portion of the extension area DEP may be exposed flat to the outside. The extension area DEP may extend from the fixed area DFP in the first direction DR1. As shown in FIG. 5B, a portion of each of the fixed area DFP and the extension area DEP may extend along the first direction DR1 in the extended mode. When the display device DD is in a reduced mode, a portion of the extension area DEP may be located below the fixed area DFP as shown in FIG. 5A.

The support plate MTP may be located below the display module DM. The display module DM may be supported by the support plate MTP. The support plate MTP may include a first plate MTP1 and a second plate MTP2. The first plate MTP1 may overlap the fixed area DFP. The second plate MTP2 may overlap the extension area DEP. The second plate MTP2 may be coupled to a bottom surface of the first plate MTP1.

When the display device DD is folded (see FIG. 1), the first plate MTP1 may be folded on an axis parallel to the second direction DR2. When the display device DD switches from a reduced mode to an extended mode (see FIG. 1), tensile stress may be applied to the second plate MTP2.

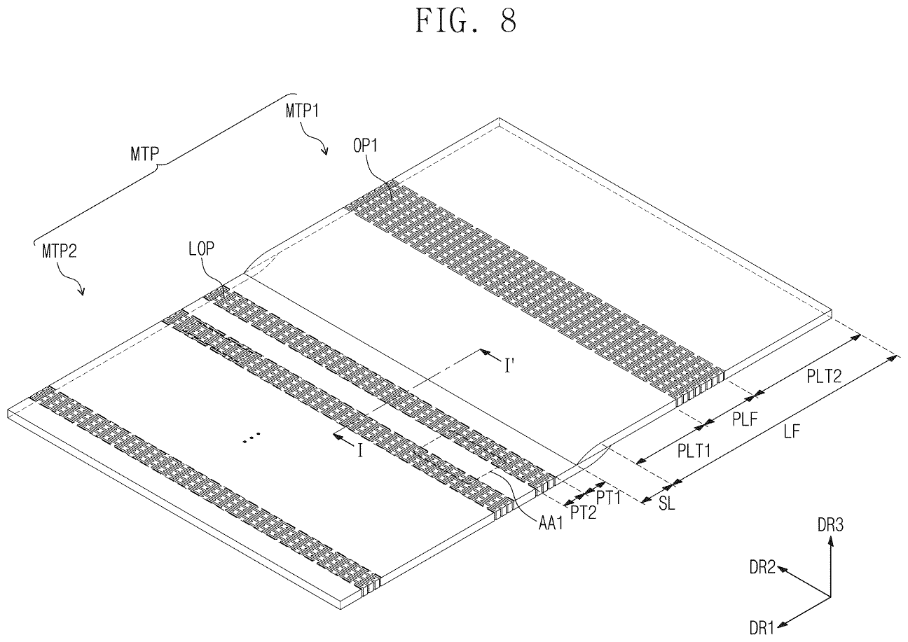

Because the first plate MTP1 and the second plate MTP2 are separately manufactured and combined, the first plate MTP1 and the second plate MTP2 may be made of materials with different respective elastic moduli. The elastic modulus of the first plate MTP1 may be less than that of the second plate MTP2. Accordingly, the first plate MTP1 having a relatively smaller elastic modulus may be suitably folded. Also, even if tensile stress is applied to the second plate MTP2, which has a relatively larger elastic modulus than that of the first plate MTP1, deformation of the second plate MTP2 may be reduced or prevented. Therefore, the folding reliability and sliding reliability of the display device DD (see FIG. 1) may be improved. The support plate MTP will be described in detail below with reference to FIG. 8.

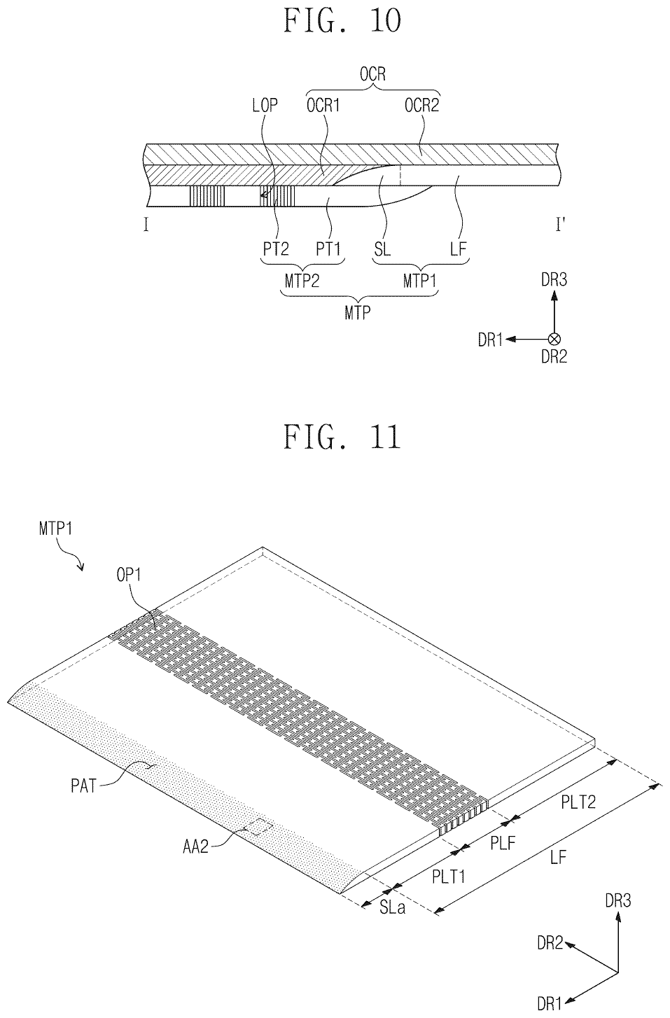

The adhesion member OCR (e.g., OCR1, OCR2) may be located between the display module DM and the support plate MTP. The adhesion member OCR may include a first adhesion member OCR1 and a second adhesion member OCR2. The first adhesion member OCR1 may be located on a top surface of one side of the first plate MTP1, and on a top surface of the second plate MTP2 (as used herein, “located on” may mean “above”). The aforementioned one side of the first plate MTP1 may be defined as the side adjacent to the second plate MTP2. The second adhesion member OCR2 may be located on a top surface of the first adhesion member OCR1 and on the top surface of the first plate MTP1. The adhesion member OCR will be described in detail with reference to FIG. 10.

The support bars MSB may be coupled to a bottom surface of the support plate MTP. The display module DM may be supported by the support plate MTP and the support bars MSB located below the display module DM.

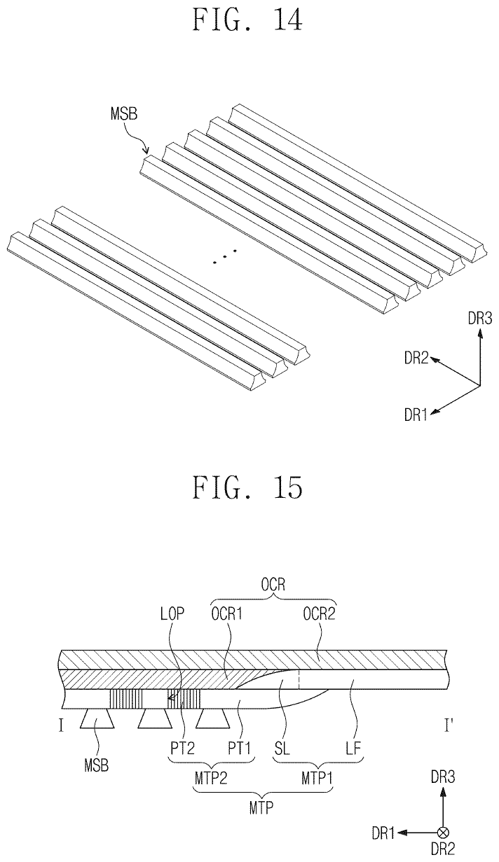

The support plate MTP and the support bars MSB may include metallic materials, such as stainless steel (e.g., SUS 316), however, the metallic materials of the support plate MTP and the support bars MSB are not limited thereto. The support plate MTP and the support bars MSB may include non-metallic materials, such as plastic. The support bars MSB will be described in detail with reference to FIG. 14.

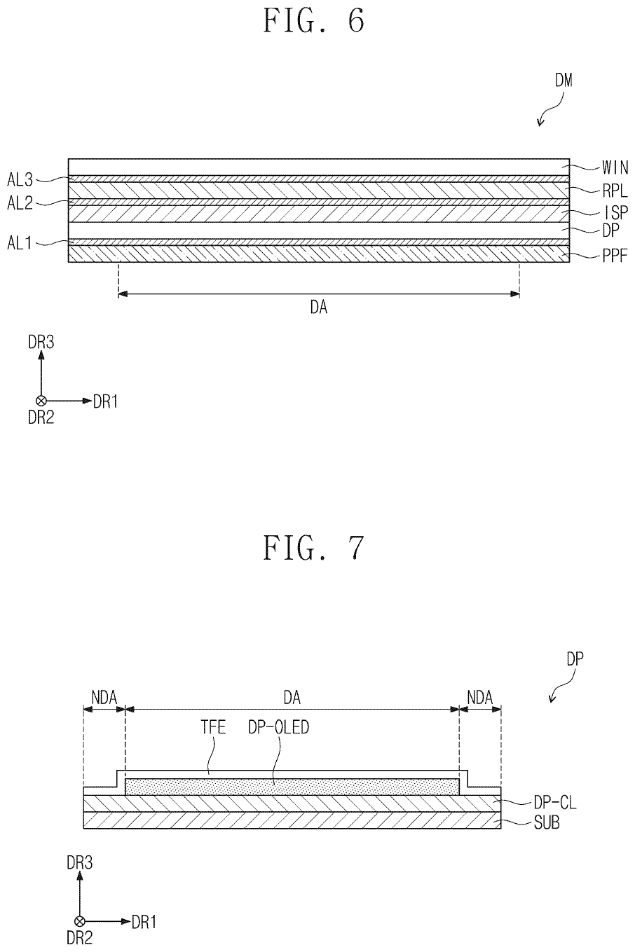

FIG. 6 is a view of the display module shown in FIG. 5A.

Referring to FIG. 6, the display module DM may include a display panel DP, an input sensor ISP, an anti-reflective layer RPL, a window WIN, a panel protection film PPF, and first to third adhesion layers AL1 to AL3.

The display panel DP may be a flexible display panel. The display panel DP according to one or more embodiments of the present disclosure may be an emissive display panel, and is not limited thereto. For example, the display panel DP may be an organic light-emitting display panel or an inorganic light-emitting display panel. A light-emitting layer of the organic light-emitting display panel may include organic light-emitting materials. A light-emitting layer of the inorganic light-emitting display panel may include quantum dots and quantum rods. Hereinafter, the display panel DP will be described as an organic light-emitting display panel.

The input sensor ISP may be located on the display panel DP. In one or more embodiments, the input sensor ISP may include a plurality of sensors for sensing external inputs in a capacitive manner. The input sensor ISP may be directly manufactured on the display panel DP during the manufacturing of the display device DD. However, the present disclosure is not limited thereto, and the input sensor ISP may be manufactured as a separate panel from the display panel DP, and may be attached to the display panel DP by an adhesion layer.

The anti-reflective layer RPL may be located above the input sensor ISP. The anti-reflective layer RPL may be defined as an external light anti-reflection film. The anti-reflective layer RPL may reduce the reflectance of external light incident from above the display device DD toward the display panel DP.

When external light that has emitted toward the display panel DP is reflected from the display panel DP and provided back to the external user, the user may recognize the external light. To reduce or prevent the likelihood of such a phenomenon, for example, the anti-reflective layer RPL may include a plurality of color filters that display the color that is the same as that of the pixels of the display panel DP.

The color filters may filter the external light to attain the color of the pixels. In such a case, the external light may not be visible to the user. However, the present disclosure is not limited thereto, and the anti-reflective layer RPL may include a retarder and/or a polarizer to reduce the reflectance of external light.

The window WIN may be located above the anti-reflective layer RPL. The window WIN may protect the display panel DP, the input sensor ISP, and the anti-reflective layer RPL from external scratches and impacts.

The panel protection film PPF may be located below the display panel DP. The panel protection film PPF may protect the lower part of the display panel DP. The panel protection film PPF may include flexible plastic materials, such as polyethylene terephthalate (PET).

The first adhesion layer AL1 may be located between the display panel DP and the panel protection film PPF, and the display panel DP and the panel protection film PPF may be attached to each other by the first adhesion layer AL1. The second adhesion layer AL2 may be located between the anti-reflective layer RPL and the input sensor ISP, and the anti-reflective layer RPL and the input sensor ISP may be attached to each other by the second adhesion layer AL2. The third adhesion layer AL3 may be located between the window WIN and the anti-reflective layer RPL, and the window WIN and the anti-reflective layer RPL may be attached to each other by the third adhesion layer AL3.

FIG. 7 is a cross-sectional view of the display panel shown in FIG. 6.

For example, FIG. 7 illustrates a cross-sectional view of the display panel DP when viewed from the second direction DR2.

Referring to FIG. 7, the display panel DP may include a substrate SUB, a circuit element layer DP-CL located on the substrate SUB, a display element layer DP-OLED located on the circuit element layer DP-CL, and a thin film encapsulation layer TFE located on the display element layer DP-OLED.

The substrate SUB may include a display area DA, and a non-display area NDA surrounding the display area DA (e.g., in plan view). The substrate SUB may include flexible plastic materials, such as polyimide (PI). The display element layer DP-OLED may be located on the display area DA.

A plurality of pixels may be located on the circuit element layer DP-CL and the display element layer DP-OLED. Each of the pixel may include transistors located on the circuit element layer DP-CL, and a light-emitting element located on the display element layer DP-OLED and connected to the transistors. The configuration of the pixel will be described in detail below.

The thin film encapsulation layer TFE may be located on the circuit element layer DP-CL to cover the display element layer DP-OLED. The thin film encapsulation layer TFE may protect the pixels from moisture, oxygen, and external foreign substances.

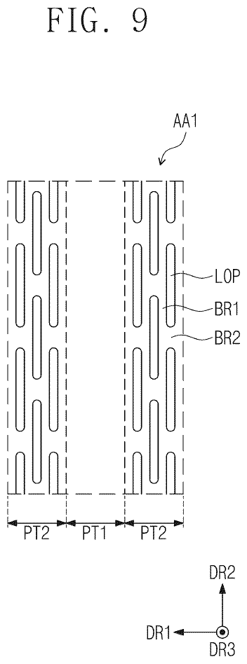

FIG. 8 is a perspective view of the support plate shown in FIG. 5A. FIG. 9 is an enlarged plan view of the first area AA1 shown in FIG. 8. FIG. 10 is a cross-sectional view of a portion taken along the line I-I′ shown in FIG. 8.

For example, in FIG. 10, the adhesion member OCR is located on the support plate MTP.

In descriptions of components illustrated in FIGS. 8 and 10, the same components as those described with reference to the above-described drawings will be omitted or briefly described.

Referring to FIGS. 5A and 8, the support plate MTP may include the first plate MTP1 and the second plate MTP2. The first plate MTP1 and the second plate MTP2 may be arranged in the first direction DR1.

The one side of the first plate MTP1 adjacent to the second plate MTP2, which is one of the sides that are opposite to each other in the first direction, may include an inclined surface. The thickness of the one side of the first plate MTP1 may be less than that of the other side of the first plate MTP1.

The first plate MTP1 may include a flat part LF and an inclined part SL. The flat part LF may be parallel to the plane defined by the first direction DR1 and the second direction DR2. The flat part LF may include a first non-folding portion PLT1, a folding portion PLF, and a second non-folding portion PLT2. The first non-folding portion PLT1, the folding portion PLF, and the second non-folding portion PLT2 may be arranged in the first direction DR1. The first non-folding portion PLT1 may overlap the first non-folding area NFA1. The folding portion PLF may overlap the folding area FA. The second non-folding portion PLT2 may overlap the second non-folding area NFA2.

The first openings OP1 may be defined in the folding portion PLF. The first openings OP1 may be arranged in a pattern (e.g., predetermined pattern). The first openings OP1 may be arranged in a grid shape to form a grid pattern in the folding portion PLF.

By defining the first openings OP1 in the folding portion PLF, the area of the folding portion PLF may be reduced, and the rigidity of the folding portion PLF may be decreased. Therefore, the flexibility of the folding portion PLF may be higher in the case in which the first openings OP1 are defined in the folding portion PLF than in the case in which the first openings OP1 are not defined in the folding portion PLF. As a result, the folding portion PLF may be folded more effectively.

The inclined part SL may extend in the first direction DR1 from the flat part LF. The inclined part SL may be located on one side of the flat part LF, which is adjacent to the second plate MTP2, of the sides that are opposite to each other in the first direction DR1. The inclined part SL and the flat part LF may be integrally provided.

The top surface of the inclined part SL may include an inclined surface. The height of the top surface of the inclined part SL may decrease as it extends away from the flat part LF. The height of the top surface of the inclined part SL may be lower than the height of the top surface of the flat part LF. The thickness of the inclined part SL may decrease as it extends far away from the flat part LF.

Referring to FIGS. 8 and 10, the second plate MTP2 may be located on (e.g., may be below) the bottom surface of the first plate MTP1. The height of the top surface of the first plate MTP1 and the height of the top surface of the second plate MTP2 may be different from each other. The top surface of the first plate MTP1 and the top surface of the second plate MTP2 may have a height difference. The second plate MTP2 may be located on the bottom surface of the inclined part SL. The second plate MTP2 may overlap the inclined part SL.

If the top surface of one of the sides (of the first plate MTP1 that are opposite to each other in the first direction DR1) does not have an incline, the height difference between the top surface of the first plate MTP1 and the top surface of the second plate MTP2 may change abruptly. Accordingly, the adhesion member OCR overlapping the boundary between the first plate MTP1 and the second plate MTP2 may be recessed. Thus, the surface quality of the display module DM located on the adhesion member OCR may deteriorate.

Due the inclined part SL according to one or more embodiments of the present disclosure, the height difference between the top surface of the first plate MTP1 and the top surface of the second plate MTP2 may be gentle or gradual. Thus, the inclined part SL may reduce or prevent recession of the adhesion member OCR located at the boundary between the first plate MTP1 and the second plate MTP2. Therefore, the surface quality of the display module DM (see FIG. 5A) located on the adhesion member OCR may be improved.

Referring to FIGS. 8 and 9, the second plate MTP2 may include a plurality of first portions PT1 and a plurality of second portions PT2. The first portions PT1 may extend in the second direction DR2. The second portions PT2 may extend in the second direction DR2.

A plurality of flexible openings LOP may be defined in the second portions PT2. Flexible openings LOP may not be defined in, or may be omitted from, the first portions PT1. When viewed in a plane, the flexible openings LOP may be arranged in the first direction DR1 and the second direction DR2. The flexible openings LOP may extend longer in the second direction DR2 than in the first direction DR1. The flexible openings LOP arranged in the h-th row and the flexible openings LOP arranged in the (h+1)-th row may be alternately arranged. The rows may correspond to the second direction DR2. As used above, h is a natural number.

The second portions PT2 may include first branch parts BR1 and second branch parts BR2. The first branch parts BR1 may be located between the flexible openings LOP adjacent to each other in the first direction DR1. The second branch parts BR2 may be located between the flexible openings LOP adjacent to each other in the second direction DR2. The first branch parts BR1 may extend in the second direction DR2, and the second branch parts BR2 may extend in the first direction DR1. The flexible openings LOP may be defined by the first and second branch parts BR1, BR2. As a result, as shown in FIGS. 5A and 5B, the second plate may be suitably bent and accommodated within the second case CS (see FIG. 4).

Referring to FIGS. 5A and 10, the adhesion member OCR may be located on the support plate MTP. The adhesion member OCR may be located between the support plate MTP and the display module DM. The support plate MTP and the display module DM may be attached to each other by the adhesion member OCR.

The adhesion member OCR may include a first adhesion part OCR1 and a second adhesion part OCR2. The first adhesion part OCR1 may be located on the top surface of the inclined part SL and the top surface of the second plate MTP2. The bottom surface of the first adhesion part OCR1 may have a shape corresponding to the top surface of the inclined part SL and the top surface of the second plate MTP2. A portion of the bottom surface of the first adhesion part OCR1 may have an inclined surface. The other portion of the bottom surface of the first adhesion part OCR1 may have a plane defined by the first direction DR1 and the second direction DR2.

The height of the top surface of the first adhesion part OCR1 may be the same as the height of the top surface of the flat part LF. The top surface of the first adhesion part OCR1 and the top surface of the flat part LF may be located on the same plane. As the first adhesion part OCR1 is located on the top surface of the inclined part SL and the top surface of the second plate MTP2, it may compensate for the height difference between the top surface of the first plate MTP1 and the top surface of the second plate MTP2. Accordingly, the second adhesion part OCR2 described below may be located on the top surface of the flat first adhesion part OCR1 and the top surface of the flat part LF. Therefore, the surface quality of the display module DM (see FIG. 5A) may be improved on the boundary between the first plate MTP1 and the second plate MTP2.

The first adhesion part OCR1 may include an optically clear resin. For example, the first adhesion part OCR1 may be an OCR adhesion, however it is not limited thereto. The first adhesion part OCR1 may have an elastic force (e.g., predetermined elastic force).

The second adhesion part OCR2 may be located on the top surface of the first plate MTP1 and on the top surface of the first adhesion part OCR1. The second adhesion part OCR2 may be an OCR adhesion, however it is not limited thereto. For example, the elastic modulus of the second adhesion part OCR2 may be less than about 50 kPa at about −20° C. The elastic modulus of the second adhesion part OCR2 may be about 20 kPa to about 30 kPa at about 25° C.

Because the adhesion member OCR includes the first adhesion part OCR1 and the second adhesion part OCR2, it may be made of resins with different elastic modulus. The elastic modulus of the first adhesion part OCR1 may be different from that of the second adhesion part OCR2. The elastic modulus of the first adhesion part OCR1 may be greater than that of the second adhesion part OCR2.

When the display device DD (see FIG. 1) switches to an extended mode or a reduced mode, even if tensile stress is applied to the first adhesion part OCR1, deformation of the first adhesion part OCR1, which has a relatively larger elastic modulus, may be reduced or prevented. Additionally, because the second adhesion part OCR2, which has a smaller elastic modulus than that of the first adhesion part OCR1, is located on the top surface of the first plate MTP1, the display device DD (see FIG. 1) may be suitably folded. Therefore, the folding characteristics and sliding characteristics of the display device DD (see FIG. 1) may be improved.

Furthermore, when the adhesion member OCR includes a single material, the thickness of the adhesion member OCR located on the second plate MTP2 may increase. Here, when an impact is applied from above to the adhesion member OCR, the portion of the adhesion member OCR that received the impact may be recessed. The depth of recess may be proportional to the thickness of the adhesion member OCR. Accordingly, the surface quality of the display module DM (see FIG. 5A) may decrease.

However, because the adhesion member OCR has a laminated structure with multiple layers, the thicknesses of each of the first adhesion part OCR1 and the second adhesion part OCR2 may be reduced. Accordingly, even if the second adhesion part OCR2 is recessed, the depth of the depression may be shallow. Therefore, the surface quality of the display module DM (see FIG. 5A) may be improved.

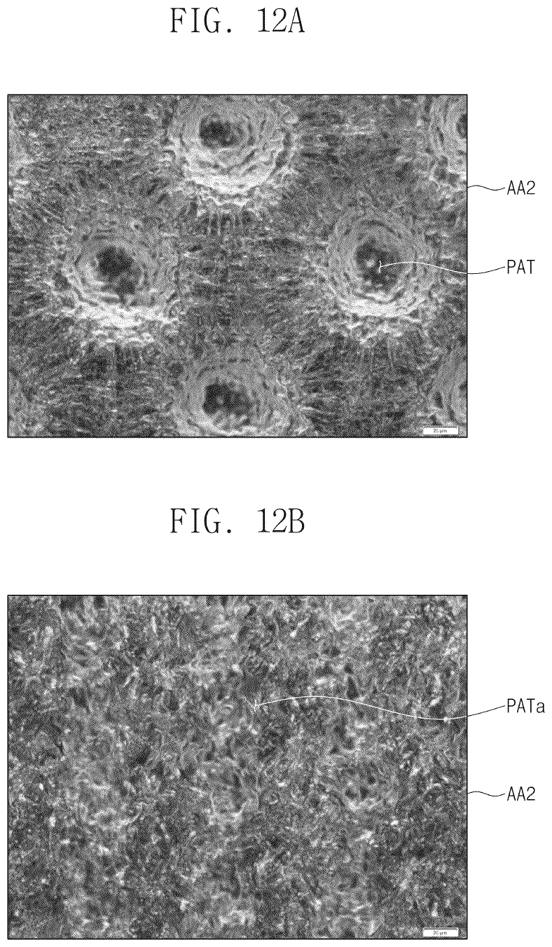

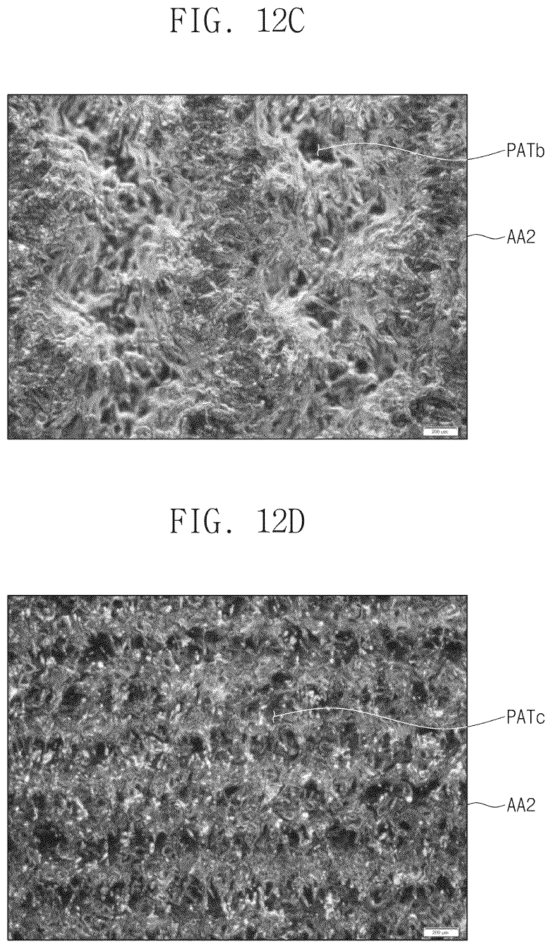

FIG. 11 is a perspective view of the first plate according to one or more embodiments of the present disclosure. FIGS. 12A to 12D are enlarged plan views of the second area AA2 shown in FIG. 11.

In descriptions of components illustrated in FIGS. 11 and 12D, the same components as those described with reference to the above-described drawings will be omitted or briefly described.

Referring to FIGS. 11 to 12D, the top surface of the inclined part SL may include pattern parts PAT, PATa, PATb, and PATc. The pattern parts PAT, PATa, PATb, and PATc may be processed by laser, or may be formed through etching. As shown in FIGS. 12A to 12D, the shapes of the pattern parts PAT, PATa, PATb, and PATc may vary.

Referring to FIG. 11, because the pattern parts PAT are located on the top surface of the inclined part SLa, the bonding force between the top surface of the inclined part SLa and the bottom surface of the first adhesion part OCR1 (see FIG. 10) may increase. Accordingly, even if the display device DD (see FIG. 1) repeatedly switches between reduced mode and extended mode, the likelihood of the first adhesion part OCR1 (see FIG. 10) being separated from the inclined part Sla may be reduced or prevented. Thus, defects of the display device DD (see FIG. 1) may be reduced or prevented.

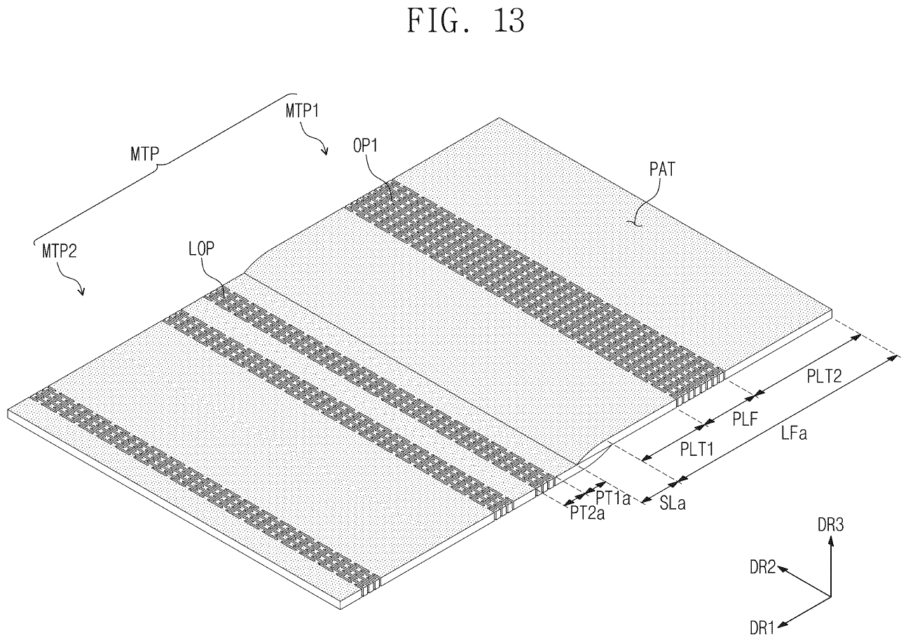

FIG. 13 is a perspective view of the first plate and the second plate according to one or more embodiments of the present disclosure.

In descriptions of components illustrated in FIG. 13, the same components as those described with reference to the above-described drawings will be omitted or briefly described.

Referring to FIG. 13, the top surface of the first plate MTP1 and the top surface of the second plate MTP2 may include pattern parts PAT. The pattern parts PAT may be located on the top surface of the flat part LFa, the top surface of the inclined part SLa, the top surface of the first portion PT1a, and the top surface of the second portion PT2a. The pattern parts PAT may be formed through laser or etching.

Because the pattern parts PAT are located on the top surface of the first plate MTP1 and the top surface of the second plate MTP2, the bonding force between the top surface of the inclined part SLa and the bottom surface of the first adhesion part OCR1 (see FIG. 10), and the bonding force between the top surface of the second plate MTP2 and the bottom surface of the first adhesion part OCR1 (see FIG. 10), may increase. Also, the bonding force between the bottom surface of the second adhesion part OCR2 (see FIG. 10) and the top surface of the flat part LFa may increase. Accordingly, when the display device DD (see FIG. 1) switches between the extended mode and the reduced mode, the likelihood of separation of the first adhesion part OCR1 (see FIG. 10) from the top surface of the inclined part SLa and the top surface of the second plate MTP2 may be reduced or prevented. When the display device DD (see FIG. 1) is folded or unfolded, the likelihood of separation of the second adhesion part OCR2 (see FIG. 10) from the flat part LFa may be reduced or prevented. Thus, defects of the display device DD (see FIG. 1) may be reduced or prevented.

FIG. 14 is a perspective view of the support bars shown in FIG. 5A. FIG. 15 is a cross-sectional view for explaining the support bars coupled to the bottom surface of the second plate.

For example, FIG. 15 is a cross-sectional view of a portion taken along the line I-I′ shown in FIG. 8.

In descriptions of components illustrated in FIGS. 14 to 15, the same components as those described with reference to the above-described drawings will be omitted or briefly described.

Referring to FIG. 14, the support bars MSB may be arranged in the first direction DR1, and may extend in the second direction DR2. The support bars MSB may include metallic materials, such as stainless steel (e.g., SUS 316), however the metallic materials of the support bars MSB are not limited thereto. The support bars MSB may include non-metallic materials, such as plastic.

Referring to FIGS. 14 and 15, the support bars MSB may be coupled to the bottom surface of the support plate MTP. The support bars MSB may be coupled to the bottom surface of the second plate MTP2. The support bars MSB may be coupled to the bottom surface of the first portions PT1. The areas between the support bars MSB adjacent to each other in the first direction DR1 may overlap the flexible openings LOP defined in the second portions PT2 shown in FIG. 9.

In one or more embodiments, the support bars MSB may be located on the outer surface of a roller located in the case CS, and when the roller rotates around an axis parallel to the second direction DR2, the support bars MSB may move toward the inside or outside of the case along the outer surface of the roller. When the support bars MSB move, the support plate MTP coupled to the support bars MSB and the display module DM may also move.

Although described with reference to some embodiments, those skilled in the art will understand that various modifications and changes may be made without departing from the spirit and scope of the present disclosure as described in the claims, with functional equivalents thereof to be included therein. Furthermore, the embodiments disclosed in the present disclosure are not intended to limit the technical scope of the present disclosure, and all technical ideas within the scope of the claims and their equivalents should be interpreted as being included in the scope of the present disclosure.

According to the disclosed embodiments, one side of the first plate adjacent to the second plate may have an inclination. Accordingly, it may reduce or prevent the likelihood of the adhesion member, which is located at the boundary between the first plate and the second plate, receding, thereby improving the surface quality of the display device.

According to the disclosed embodiments, the height difference between the first plate and the second plate may be compensated by the first adhesion part. Accordingly, the surface quality of the display module overlapping the boundary between the first plate and the second plate may be improved.

Although the embodiments of the present disclosure have been described, it is understood that the present disclosure should not be limited to these embodiments but various changes and modifications can be made by one ordinary skilled in the art within the spirit and scope of the present disclosure as hereinafter claimed.

1 what is claimed is:

1. A display device comprising:
a display panel comprising a fixed area, and an extension area extending in a first direction from the fixed area;
a support plate comprising:
a first plate overlapping the fixed area, and comprising a flat part parallel to a plane defined by the first direction and by a second direction crossing the first direction, and an inclined part extending in the first direction from the flat part; and
a second plate overlapping the extension area, and below a bottom surface of the inclined part; and
an adhesion member between the display panel and the support plate.

2. The display device of claim 1, wherein a height of a top surface of the inclined part decreases toward the second plate.

3. The display device of claim 2, wherein a top surface of the first plate and a top surface of the second plate have a height difference.

4. The display device of claim 3, wherein the adhesion member comprises:
a first adhesion part above the top surface of the second plate and the top surface of the inclined part; and
a second adhesion part above a top surface of the flat part and a top surface of the first adhesion part, and
wherein an elastic modulus of the first adhesion part is greater than an elastic modulus of the second adhesion part.

5. The display device of claim 4, wherein a height of the top surface of the first adhesion part is the same as a height of the top surface of the flat part.

6. The display device of claim 4, wherein the top surface of the inclined part comprises a pattern part.

7. The display device of claim 4, wherein the top surface of the first plate and the top surface of the second plate comprise a pattern part.

8. The display device of claim 1, wherein the flat part comprises a first non-folding part, a folding part defining openings, and a second non-folding part arranged in the first direction.

9. The display device of claim 8, wherein the second plate comprises:
first portions parallel to the plane defined by the first direction and the second direction; and
second portions respectively between adjacent ones of the first portions that are adjacent to each other in the first direction, and defining flexible openings.

10. The display device of claim 9, further comprising support bars coupled to bottom surfaces of the first portions, arranged in the first direction, and extending in the second direction.

11. A display device comprising:
a display panel comprising a fixed area, and an extension area extending in a first direction from the fixed area;
a second plate below the extension area;
1 a first plate below the fixed area, and having one side, which is adjacent to the second plate and which is opposite to an opposite side in the first direction, having a thickness that is less than a thickness of the opposite side;
support bars coupled to a bottom surface of the second plate; and
an adhesion member between the display panel and the first plate, and between the display panel and the second plate.

12. The display device of claim 11, wherein a height of a top surface of the one side of the first plate is lower than a height of a top surface of the opposite side of the first plate, and
wherein the top surface of the one side of the first plate is inclined.

13. The display device of claim 11, wherein the second plate overlaps the one side of the first plate.

14. The display device of claim 11, wherein the adhesion member comprises:
a first adhesion part above a top surface of the one side of the first plate and above a top surface of the second plate; and
a second adhesion part above a top surface of the first adhesion part and above a top surface of the opposite side of the first plate.

15. The display device of claim 14, wherein a height of the top surface of the first adhesion part is the same as a height of the top surface of the opposite side of the first plate.

16. The display device of claim 14, wherein the top surface of the one side of the first plate comprises a pattern part.

17. The display device of claim 14, wherein a top surface of the first plate and the top surface of the second plate comprise pattern parts.

18. The display device of claim 14, wherein an elastic modulus of the first adhesion part is greater than an elastic modulus of the second adhesion part.

19. An electronic device comprising a display device comprising:
a display panel comprising a fixed area, and an extension area extending in a first direction from the fixed area;
a support plate comprising:
a first plate overlapping the fixed area, and comprising a flat part parallel to a plane defined by the first direction and by a second direction crossing the first direction, and an inclined part extending in the first direction from the flat part; and
a second plate overlapping the extension area, and below a bottom surface of the inclined part; and
an adhesion member between the display panel and the support plate.

20. The electronic device of claim 19, wherein the electronic device comprises a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, or a head-mounted display (HMD).
